(19) United States
(12) Patent Application Publication
(10) Pub. No.: US 2021/0170667 A1
(43) Pub. Date: Jun. 10, 2021

(54) An Imprinted Polymeric Substrate

(71) Applicant: AGENCY FOR SCIENCE, TECHNOLOGY AND RESEARCH, Singapore (SG)

(72) Inventors: Yeong Yuh Lee, Singapore (SG); Qunya Ong, Singapore (SG); Fung Ling Yap, Singapore (SG); Siew Ling Karen Chong, Singapore (SG)

(21) Appl. No.: 16/768,966

(22) PCT Filed: Dec. 6, 2018
(86) PCT No.: PCT/SG2018/050595

§ 371 Date: Jun. 2, 2020

(30) Foreign Application Priority Data
Dec. 6, 2017 (SG) 10201710108W

(51) Int. Cl. B29C 59/02; B29C 39/02; B29C 39/10; B82Y 40/00

(52) U.S. Cl. CPC B29C 59/021; B29C 59/022; B29C 33/424; B29C 39/10; B82Y 40/00; B29C 39/026

(57) ABSTRACT

The present invention relates to a method for preparing a plurality of imprints on an inner surface of a polymeric substrate comprising the steps of:
a) contacting a liquid polymeric mixture with a mold having an imprint forming surface thereon;
b) curing the liquid polymeric mixture of step a) to form said polymeric substrate having said plurality imprints on said inner surface, when cured; and
c) removing said mold from said polymeric substrate. There is also provided a method of forming the mold having the imprint forming surface thereon.

### CROSS-REFERENCE TO RELATED APPLICATION

This application claims priority to Singapore application number 10201710108W filed on 6 Dec. 2017, the disclosure of which is hereby incorporated by reference.

### TECHNICAL FIELD

The present invention generally relates to a method of preparing a polymeric substrate having a plurality of imprints on its inner surface and a method of preparing a mold.

### BACKGROUND ART

Micro- or nano-structures or -patterns or -imprints on the inner luminal surface of polymeric materials have attracted growing research interests as they may be used as an alternative to coatings, which are usually applied on tubings to achieve additional functionalities. Such micro or nano-structures may impart a wide spectrum of functionalities, which may include but not limited to superhydrophobicity, lubricity, improved passive mixing, reduced biofouling, reduced haemolysis, anti-bacterial and enhanced ultrasound visibility. More recently, the micro- or nano-structured tubings are used in flow lines in hydraulic systems for the medical applications such as in blood pump tubing and as catheters.

Despite their promising properties and potential applications as outlined above, current processes for fabricating the micro- or nano-structures or -patterns remain challenging primarily due to the complex fabricating process. The inherent process challenges such as alignment issues may result in the loss of design, high costs, low through-puts and material constraints. For instance, the fabrication of nano-structures in polymers via molding has seen limited commercial applications to date. Replication of sub 10-nm features remains difficult to obtain reproducibly due to the lateral collapse of the features in the polymeric replica as well as the defects densities.

The present invention therefore provides an alternative method to fabricate imprinted materials that overcomes, or at least ameliorates, one or more of the disadvantages described above.

### SUMMARY

In one aspect, there is provided a method of forming a plurality of imprints on an inner surface of a polymeric substrate comprising the steps of:

a) contacting a liquid polymeric mixture with a mold having an imprint forming surface thereon;

b) curing the liquid polymeric mixture of step a) to form said polymeric substrate having said plurality imprints on said inner surface, when cured; and

c) removing said mold from said polymeric substrate.

In another aspect, there is provided a method of forming a mold having an imprint forming surface thereon, wherein said method is a nanoimprinting method, a micromachining method or a self-assembly method.

Advantageously, the method disclosed herein may produce the plurality of imprints in the form of micro- or nano-structures having high-aspect ratio.

More advantageously, the method as defined herein may form isotropic and anisotropic micro- or nano-structures.

Still advantageously, the micro- or nano-structured tubings produced by the method defined herein may be relatively long (˜10 cm).

Further advantageously, the micro- or nano-structured tubings produced by the method defined above may typically be re-used whereby the tubings can be both elastic and non-elastic (stiff).

In another aspect, there is provided a polymeric substrate prepared by the method as defined herein.

In another aspect, there is provided a mold prepared by the method as defined above.

### Definitions

The following words and terms used herein shall have the meaning indicated:

The term ‘organosilicon’ is to be interpreted broadly to refer to any organometallic compounds containing carbon-silicon bonds, which may include monomeric, oligomeric or polymeric form thereof.

The term “polyurethane” as used herein refers to macromolecules in the form of polymers, co-polymers or segmented polymers or segmented co-polymers which contain at least one urethane linkage. The urethane group has the general structure (—O—(CO)—NR—) where (CO) defines a carbonyl group C═O, and R is hydrogen or an alkyl group.

The term “alkyl” as a group or part of a group used in the present disclosure refers to a straight or branched aliphatic hydrocarbon group to be interpreted broadly, having from 1 to 16 carbon atoms, e.g., 1, 2, 3, 4, 5, 6, 7, 8, 9, 10, 11, 12, 13, 14, 15 or 16 carbon atoms, preferably a C₁-C₁₆ alkyl, C₁-C₁₂ alkyl, more preferably a C₁-C₁₀ alkyl, most preferably C₁-C₆ alkyl unless otherwise noted. Examples of suitable straight and branched alkyl substituents include but is not limited to, methyl, ethyl, 1-propyl, isopropyl, 1-butyl, 2-butyl, isobutyl, tert-butyl, amyl, 1,2-dimethylpropyl, 1,1-dimethylpropyl, pentyl, isopentyl, hexyl, 4-methylpentyl, 1-methylpentyl, 2-methylpentyl, 3-methylpentyl, 2,2-dimethylbutyl, 3,3-dimethylbutyl, 1,2-dimethylbutyl, 1,3-dimethylbutyl, 5-methylheptyl, 1-methylheptyl, octyl, nonyl, decyl, undecyl, 2,2,3-trimethyl-undecyl, dodecyl, 2,2-dimethyl-dodecyl, tridecyl, 2-methyl-tridecyl, 2-methyl-tridecyl, tetradecyl, 2-methyl-tetradecyl, pentadecyl, 2-methyl-pentadecyl, hexadecyl, 2-methyl-hexadecyl and the like. The alkyl may be optionally substituted with another functional group such as alkyl but not limited to it.

The term “curing” as used in the present disclosure refers to the toughening or hardening of a polymeric material, which may occur via cross-linking of polymer chains. Therefore, unless otherwise specified, the curing process refers to a solidification process of the polymeric material.

The unit “micron(s)” as used in the present disclosure may be used interchangeable with “micrometer(s)” or “μm”.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means+/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### Detailed Disclosure of Embodiments

Exemplary, non-limiting embodiments of a method of forming a plurality of imprints on an inner surface of a polymeric substrate will now be disclosed.

The method of forming said plurality of imprints on the inner surface of the polymeric substrate comprising the steps of:

a) contacting a liquid polymeric mixture with a mold having an imprint forming surface thereon;

b) curing the liquid polymeric mixture of step a) to form said polymeric substrate having said plurality imprints on said inner surface, when cured; and

c) removing said mold from said polymeric substrate.

It is to be noted that the liquid polymeric mixture above refers to a liquid mixture prior to a curing step as defined above. Hence, the liquid polymeric mixture may be in the form of a pre-polymer, which upon curing is converted into a polymer and subsequently into a network of cross-linked polymer. The above liquid polymeric mixture essentially may comprise polymeric organosilicon compounds or polyurethanes. The polymeric organosilicon compounds may be selected from the group consisting of polymethylhydrosiloxane (PMHS), polydimethylsiloxane (PDMS), polyethylmethylsiloxane (PEMS), polydiethylsiloxane (PDES) and blends thereof. The polymeric organosilicon compounds shown here are not limiting. It may therefore encompass other suitable polymeric organosilicon compounds. The polyurethane as used herein is to be understood to encompass polymers or co-polymers or segmented polymers or segmented co-polymers containing a plurality of urethane linkages as defined above.

For clarity purposes, prior to the curing step as will be discussed below, the aforesaid polymeric organosilicon compounds may be in the state whereby the polymeric organosilicon compounds are already in the polymeric form but not cross-linked. Only when subjected to the curing process, such polymeric organosilicon compounds form a cross-linked network of polymers. The existence of such crosslinking may be indicated by changes in the physical properties or state of the polymers such as from liquid to solid.

The curing step of the above polymeric organosilicon compounds may be undertaken in the presence of heat or UV irradiation. The curing step may be undertaken when the liquid polymeric mixture is in contact with the mold. The curing step, which occurs in the presence of heat may be referred as thermocuring. The thermocuring may be undertaken by subjecting the liquid polymeric mixture as defined above to a heat source, which then will undergo a hardening process. Alternatively, the curing process may be undertaken in the presence of an ultraviolet light and visible light (UV) to initiate a photochemical reaction that generates the cross-linked polymers. The curing process described here is not limiting. Hence, other suitable curing techniques such as microwave-assisted curing may also be used, when suitable.

For thermal curing, a suitable heating temperature may be selected in the range from about 40° C. to about 200° C. such as about 50° C., about 60° C., about 70° C., about 80° C., about 90° C., about 100° C., about 110° C., about 120° C., about 130° C., about 140° C., about 150° C., about 160° C., about 170° C., about 180° C. or about 190° C. Any other suitable temperatures within the range above may also be used. When suitable, a room temperature curing may also be undertaken that is the curing is performed at a room temperature from about 20° C. to about 30° C. In the room temperature and thermal curing, a constant or variable temperature may be used. When UV-curing is used, the curing process may be undertaken at a room temperature such as from about 20° C. to about 30° C.

For any of the curing process defined above, the curing step may be undertaken for a certain period of time such as from about 1 minute to about 24 hours, about 1 minute to about 5 minutes, about 1 minute to about 10 minutes, about 1 minute to about 20 minutes, about 1 minute to about 30 minutes (0.5 hours), about 30 minutes (0.5 hours) to about 24 hours, about 1 hour to about 24 hours, about 1 hour to about 2 hours, about 1 hour to about 5 hours, about 1 hour to about 10 hours, about 2 hours to about 5 hours, about 2 hours to about 10 hours, about 2 hours to about 24 hours, about 5 hours to about 10 hours, about 5 hours to about 18 hours, about 5 hours to about 24 hours, about 10 hours to about 18 hours, about 10 hours to about 24 hours or about 18 hours to about 24 hours. Exemplary embodiment of the thermal curing is as follow: when polydimethylsiloxane (PDMS) is used as the liquid polymeric mixture, the thermal curing process may be completed in about 5 minutes at curing temperature of about 120° C. or higher. Hence, when a lower temperature of curing is used, a longer curing time or period may be needed.

In the method as defined above, the mold having said imprint forming surface thereon may comprise a dissolvable material, temperature-dependent material or pressure-dependent material.

The dissolvable material is defined as any material that can be completely or essentially dissolved in a suitable solvent or a mixture of solvents. The dissolvable material may be a polymer or co-polymer or a blend of two or more polymers or co-polymers. Non-limiting examples of the dissolvable material may include acrylic-based polymer, acrylate-based polymer, polystyrene or mixtures thereof.

The examples of the acrylic-based polymer and the acrylate-based polymer include but not limited to poly(methacrylic acid), polyacrylic acid, poly(methyl methacrylate), poly(ethyl methacrylate), poly(propyl methacrylate), poly(propyl methacrylate), poly(isopropyl methacrylate), poly(butyl methacrylate), poly(isobutyl methacrylate), poly(hexyl methacrylate), poly(octyl methacrylate), poly(dodecylmethacrylate), poly(2-ethoxyethyl methacrylate), poly(2-hydroxyethyl methacrylate), poly(2-chloroethyl methacrylate) and poly(benzyl methacrylate).

The solvent used to dissolve the dissolvable material above is preferably an organic solvent. Non-limiting examples of the organic solvent may include acetic acid, acetone, acetonitrile, benzene, 1-butanol, 2-butanol, 2-butanone, t-butyl-alcohol, carbon tetrachloride, chloroform, cyclohexane, 1,2-dichloroethane, dimethyl formamide (DMF), dimethyl sulfoxide (DMSO), ethanol, ethyl acetate, hexane, methanol, methyl t-butyl ether (MTBE), N-methyl-2-pyrrolidinone (NMP), pentane, 1-propanol, 2-propanol, pyridine, tetrahydrofuran (THF), toluene, triethyl amine, o-xylene, m-xylene and p-xylene.

Therefore, the present disclosure also provides a method of forming the plurality of imprints on the inner surface of the polymeric substrate comprising the steps of:

a) contacting the liquid polymeric mixture with the mold having the imprint forming surface thereon, wherein the mold having the imprint forming surface thereon comprises the dissolvable material as defined above;

b) curing the liquid polymeric mixture of step a) to form said polymeric substrate having said plurality imprints on said inner surface, when cured; and

c) exposing said mold to a solvent to thereby remove said mold from said polymeric substrate.

For the above method, it is to be understood that the inner surface of the polymeric substrate may be the one in direct contact with the outer surface of the mold (such as the one represented as (109) in FIG. 1A, (125) in FIG. 1B or (135) in FIG. 1C). In the case where said polymeric substrate is in the form of tubing(s), its inner surface may be defined as a lumen. Exemplary embodiment of such inner surface of the polymeric substrate is depicted as (213) in FIG. 2A. The outer surface of the polymeric substrate, on the other hand, is the surface opposing the inner surface and is indicated as (215) in FIG. 2A. Since the outer surface of the mold is an imprint forming surface, the plurality of imprints formed on the inner surface of the polymeric substrate may be considered as the negative impression of the imprint of the outer surface of the mold.

When the mold having said imprint forming surface thereon is a temperature-dependent material, such material may be a hydrocarbon or a mixture of two or more hydrocarbons. Said hydrocarbons may be a branched, a linear or combinations thereof having twenty to forty carbon atoms. In an embodiment, said hydrocarbons may have 20, 21, 22, 23, 24, 25, 26, 27, 28, 29, 30, 31, 32, 33, 34, 35, 36, 37, 38, 39 or 40 carbons. The example of such temperature-dependent material is paraffin wax, which is a solid at room temperature (at about 20° C. to 30° C.) and turns into a liquid when heated. The melting point of the paraffin wax may be in the range of between about 35° C. to about 80° C. depending on the chain length of the hydrocarbon.

When subjected to heating, the wax melts into a liquid, after which it can then be casted into the inner spaces of the polymeric substrate having the plurality of imprints on its inner surface. Upon removal of the heat (i.e. decrease in the temperature), the wax may solidify back and its surface may essentially conform to the plurality of imprints of the inner surface of the polymeric substrate. The solidified wax may have the imprint forming surface thereon. Upon demolding, the solidified wax may advantageously be further used for forming the plurality of imprints on the inner surface of a new polymeric substrate.

In essence, when the mold having said imprint forming surface thereon is the temperature-dependent material, the step of removing the mold from the polymeric substrate may be achieved by adjusting the temperature that is by increasing the temperature. The increase in temperature may selectively cause the mold, in this instance wax, to melt but not the polymeric substrate having the plurality of imprints on the inner surface. When wax is used as the mold, the polymeric substrate may be selected from the polysiloxanes, which have much higher degradation temperature than wax. The degradation temperature of said polysiloxanes must be at least about 20° C. to about 200° C. higher than that of the wax, such as at least about 25° C., about 35° C., about 45° C., about 50° C., about 65° C., about 75° C., about 100° C., about 125° C., about 150° C. or about 175° C.

Hence, the above process may advantageously not require the presence of a solvent or a mixture of solvent as the mold can be removed by adjusting the temperature as described above and therefore it may be termed as solvent-less removal method.

Therefore, the present disclosure further provides a method of forming the plurality of imprints on the inner surface of the polymeric substrate comprising the steps of:

a) contacting the liquid polymeric mixture with the mold having the imprint forming surface thereon, wherein the mold having the imprint forming surface thereon comprises the temperature-dependent material as defined above;

b) curing the liquid polymeric mixture of step a) to form said polymeric substrate having said plurality imprints on said inner surface, when cured; and

c) subjecting the mold to a temperature that is about the melting point temperature of the mold to thereby remove said mold from said polymeric substrate.

The mold having said imprint forming surface thereon may also be a pressure-dependent material. Therefore, the shape or size of such material may be distorted when the material is subjected to a vacuum. The pressure-dependent material referred in the present disclosure may be an elastomer, which may typically have a high elastic nature. Non-limiting examples of the elastomer may include natural rubbers such as latex or synthetic rubbers, which may be nitrile rubbers, silicone rubbers, urethane rubbers, butadiene rubbers, styrene-butadiene rubbers, neoprene rubbers, chloroprene rubbers, polysulfide rubbers and Ethylene Vinyl Acetate (EVA rubbers).

The present disclosure therefore also provides a method of forming the plurality of imprints on the inner surface of the polymeric substrate comprising the steps of:

a) contacting the liquid polymeric mixture with the mold having the imprint forming surface thereon, wherein the mold having the imprint forming surface thereon comprises the pressure-dependent material as defined above;

b) curing the liquid polymeric mixture of step a) to form said polymeric substrate having said plurality imprints on said inner surface, when cured; and

c) subjecting said mold to a vacuum to thereby remove said mold from said polymeric substrate.

In some embodiments, the polymeric substrate obtained from the above method advantageously may be used as a further mold that is the polymeric substrate having the plurality of imprints on its inner surface formed by the method as defined above may serve as an external mold.

When the polymeric substrate above is used as the external mold, a pressure-dependent material, preferably in the form of hollow cylinder, may be then inserted into the external mold. In this assembly, there are two molds, that is, the “external mold” of the polymeric substrate having the plurality of imprints on its inner surface and “an internal mold”, which has been inserted as described above. The liquid polymeric mixture may be then deposited into the spaces formed between the inner and external molds followed by curing the liquid polymeric mixture. The external mold may be removed by peeling it away, whereas the internal mold may be removed by subjecting the above assembly to a vacuum.

Upon subjecting the above assembly to the vacuum, the shape and/or size of the internal mold may be distorted due to its elasticity of the internal mold. As the pressure of the air inside the internal mold is reduced relative to the atmospheric pressure, the hollow internal mold is distorted in the above assembly. The distortion or collapse of the internal mold may “demold” the internal mold from the inner wall of the cured polymeric substrate and this will allow the removal of the internal mold.

As the internal mold above has elastic nature, the internal mold may, partially or completely, return to its original shape or size (before being subjected to the vacuum) such that it may advantageously be re-used to cast another polymeric substrate after the vacuum is released. Therefore, the method above may be considered cost-effective since the internal mold may be re-used further.

The external mold as defined above may be made of various polymers, which include but not limited to polyethylene, polystyrene, polycarbonate, polymethylmethacrylate, polypropylene, and polytetrafluoroethylene. The external cylindrical mold may also be made of metal or glass or ceramics. The external mold may be in a cylindrical shape. Such external cylindrical molds may be coated with a layer of anti-stiction coatings such as PTFE (Teflon) or perfluorodecyltrichlorosilane (FDTS) to reduce adhesion between the tubings and the external mold, and facilitate demolding.

Exemplary, non-limiting embodiments of a method of forming a mold having an imprint forming surface thereon will now be disclosed.

The mold having said imprint forming surface thereon may be fabricated via an imprinting method, a machining technique or a self-assembly process. However, it is to be understood that the above methods are not limiting. Therefore, other suitable techniques capable of generating the mold having the imprint forming surface with desired topographies may also be used where appropriate. The three methods above will be discussed further as follow.

### Nano-Imprinting Method

When the imprinting method is used, the desired topographies may be imprinted or embossed on a surface of the polymeric material as defined above. Hence, for this purpose such polymeric material may be considered as a pre-mold. The suitable polymeric material used as the pre-mold is preferably polymethymethacryalate (PMMA) or polystyrene (PS). Such polymeric material may be in the form of sheets of films.

The polymeric sheets used may be preferably a thin polymeric sheet having a thickness in the range of from about 10 μm to about 100 μm, such as from about 10 μm to about 20 μm, from about 10 μm to about 40 μm, from about 10 μm to about 50 μm, from about 10 μm to about 60 μm, from about 10 μm to about 80 μm, from about 20 μm to about 40 μm, from about 20 μm to about 50 μm, from about 20 μm to about 60 μm, from about 20 μm to about 80 μm, from about 40 μm to about 50 μm, from about 40 μm to about 60 μm, from about 40 μm to about 80 μm or from about 60 μm to about 100 μm. More preferably, the thickness of the polymeric sheets is about 40 μm, about 50 μm or about 60 μm.

The polymeric sheets may be dissolved completely or partially in a solvent or a mixture of two or more solvents. The solvent is preferably an organic solvent. Non-limiting examples of the organic solvent may include acetic acid, acetone, acetonitrile, benzene, 1-butanol, 2-butanol, 2-butanone, t-butyl-alcohol, carbon tetrachloride, chloroform, cyclohexane, 1,2-dichloroethane, dimethyl formamide (DMF), dimethyl sulfoxide (DMSO), ethanol, ethyl acetate, hexane, methanol, methyl t-butyl ether (MTBE), N-methyl-2-pyrrolidinone (NMP), pentane, 1-propanol, 2-propanol, pyridine, tetrahydrofuran (THF), toluene, triethyl amine, o-xylene, m-xylene and p-xylene. It is to be noted that when the polymeric sheets can be dissolved for example in acetone, the substrate prepared by the method described herein is chemically resistant to acetone. Therefore, it is preferred that the polymeric sheets are selected in such a way that they can be dissolved in a solvent or a mixture of two or more solvents in which the substrate is chemically resistant to.

The imprinting step on the polymeric sheets above may require a two-dimensional flat master mold used to create the plurality of imprints, which may be micro- or nano-topographies. The two-dimensional flat master molds may comprise a metallic material, silicon-based material or a polymeric-based material. When the two-dimensional flat master molds are metallic materials, preferably the metal is nickel. For the two-dimensional flat master molds comprising a silicon-based material or a polymeric-based material, such silicon-based material or polymeric-based material may be the polymeric organosilicon compounds or polyurethanes as defined herein.

The imprinting step may be undertaken using a batch, continuous, semi-continuous or high-throughput imprinter under a suitable temperature and pressure for a period of time. The imprinting parameters may be adjusted during the imprinting step as appropriate or may be held constant throughout the imprinting process. When a batch imprinter system is used, the imprinting temperature may be set between about 100° C. to about 160° C., such as about 110° C., about 120° C., about 130° C., about 140° C. or about 150° C. The imprinting pressure in the batch imprinter system may be set to about 30, 40 or 50 atm. The duration of the imprinting step using batch imprinter system may be from about 200 to about 1000 seconds, preferably from about 300 to 600 seconds.

The imprinting step above may also be undertaken using UV-irradiation and such step may therefore be termed as an UV-imprinting. When UV-imprinting step is carried out, the polymeric sheet is preferably made of an UV-curable resin, which is dissolvable in a solvent after the UV-curing.

The imprinted or embossed polymeric sheets may then be adhered or attached onto an outer surface of the pre-mold in such a way that the non-imprinted surface of the polymeric film is in contact with the pre-mold to thereby form said mold having an imprint forming surface thereon. The pre-mold used for this purpose may comprise a polymeric material as aforementioned. The pre-mold as defined above has a straight parallel sides and cross-section composed of straight or curved lines. The preferred mold used in the above method is of a tube or a rod shape that is its cross-section is circular. When a tube or a cylindrical or a rod is used, the imprinted polymeric sheets may be adhered or attached thereon using an adhesive. Such adhesive may be a solid adhesive in the form of a tape made of acrylic or a liquid adhesive such as but not limited to chloroform. Upon adhesion or attachment, the mold having an imprint forming surface thereon may be formed.

It is to be understood that the mold having an imprint forming surface thereon after the adhesion or attachment above essentially may adopt or maintain the original shape of the pre-mold. For clarity purposes, if the pre-mold has a tube or rod shape, the mold having an imprint forming surface thereon may follow this tube or rod shape.

Throughout the present disclosure, unless specified otherwise, the term “mold” in a tube or a rod shape may be used interchangeably with “polymer rod”.

Therefore the present disclosure provides a method for forming a mold having an imprint forming surface thereon via a nano-imprinting method comprising the steps of:

i) imprinting the surface of a polymeric film; and

ii) adhering the imprinted polymeric film onto the outer surface of a pre-mold,

wherein the non-imprinted surface of the polymeric film is in contact with the pre-mold to thereby form said mold having the imprint forming surface thereon.

### Micro-Machining Technique

The mold having an imprint forming surface thereon as defined above may also be fabricated directly via machining techniques such as but not limited to laser, micro-electrical discharge machining (micro-EDM) or micro-milling. Any one of these aforesaid methods may selectively remove the polymeric material from defined positions on the mold's external surface to create the desired imprint forming surface with micro- or nano-patterns. Such technique enables the fabrication of seamless patterning around the circumference of the rod.

### Self-Assembly Method

Alternatively, the mold having an imprint forming surface thereon may be manufactured via a deposition of a plurality of particles selected from polystyrene (PS), polymethylmethacrylate (PMMA) or silica onto the polymeric mold. The deposition may be achieved via drawing a meniscus of particle suspension along the length of the polymeric mold. Hence, this process may be considered as a self-assembly as the deposition occurs spontaneously without an external driving force. The deposition may occur in the presence of a solvent and one or more surfactants.

Following the deposition step, closely packed or loosely packed particles with the desired micro- or nano-topographies may be formed on the outer surface of the mold. The pattern or structure of the imprint formed may depend on the type of solvents and/or surfactants used.

The mold having the imprint forming surface thereon manufactured by any one of the methods described above serves as a template for preparing the substrate having the plurality of imprints on its inner surface. As mentioned above, the substrate produced may be in the form of a tube. The tube may be prepared via a casting or a coating technique.

### Casting Method

When a casting technique is used, a liquid polymeric mixture (the liquid polymeric mixture here refers to the mixture prior to the curing step) may be deposited into spaces between the mold and an external mold, wherein said mold is inserted into said external mold. The mold of a tube or rod shape may have an imprint forming surface thereon. Therefore, when the tube mold is inserted into the external tube mold, such a system refers to two concentric layers of mold. In this configuration, the external mold may be removed after the liquid polymeric mixture is cured thereby forming said plurality of imprints on an inner surface of the polymeric substrate.

Following the deposition of the liquid polymeric mixture into the spaces as described above, the deposited liquid polymeric mixture may be optionally degassed to remove bubbles formed during the depositing step. The degassed liquid polymeric mixture may then be cured to thereby forming a polymeric substrate having said plurality imprints on its inner surface. The curing step may be undertaken in the presence of heat or UV radiation. Without being bound by theory, other suitable curing techniques may also be used in this step.

Following the above, the external mold may be removed by dissolving it in a solvent or peeling it away, followed by removing the mold having the imprint forming surface thereon such as by dissolving it in a mixture comprising two or more solvents. Since said mold must be dissolvable, material selection for said mold is therefore crucial. For example, when the mold is a polymethylmethacrylate (PMMA) or polystyrene (PS) mold, upon curing of the polymeric substrate, PMMA or PS mold may be dissolved either via pumping acetone through the tube or immersing it in acetone bath with or without stirring.

Finally, to remove any residue of the solvent from the substrate having the plurality of imprints on its inner surface, said substrate may be subjected to a washing step, wherein the washing is undertaken in a mixture of solvents. For example, when acetone is used for removing the mold, ethanol or isopropanol may be used to remove traces of acetone.

The dimensions of the substrate formed via casting method may be defined by the dimensions and/or topographies of the mold and the external mold.

Therefore, the present disclosure provides a method of forming the plurality of imprints on the inner surface of the polymeric substrate comprising the steps of:

a) contacting the liquid polymeric mixture as defined above with the mold having the imprint forming surface thereon, wherein the contacting step is undertaken via a casting technique;

b) curing the liquid polymeric mixture of step a) to form said polymeric substrate having said plurality imprints on its inner surface, when cured; and

c) removing said mold from said polymeric substrate.

As aforementioned, for the method where the contacting step is undertaken via casting process, it is to be appreciated that the inner surface of the polymeric substrate may be the one in direct contact with the outer surface of the mold (such as the one represented as (109) in FIG. 1A, (125) in FIG. 1B or (135) in FIG. 1C). In the case where said polymeric substrate is in the form of tubing(s), its inner surface may be defined as a lumen. Exemplary embodiment of such inner surface of the polymeric substrate is depicted as (213) in FIG. 2A. The outer surface of the polymeric substrate, on the other hand, is the surface opposing the inner surface and is indicated as (215) in FIG. 2A. Since the outer surface of the mold is an imprint forming surface, the plurality of imprints formed on the inner surface of the polymeric substrate may be considered as the negative impression of the imprint of the outer surface of the mold.

### Coating Method

As an alternative to the casting method described above, the plurality of imprints on the inner surface of the polymeric substrate may also be formed via a coating method. Non-limiting examples of the coating method may include spray coating, dip coating or vapour deposition. The preferred coating method of the present disclosure is a dip-coating technique. In this method, unlike the casting technique, an external mold may not be required that is the dimensions of the substrate is determined by the dimensions of the mold having the imprint forming surface thereon and the parameters used in the coating step.

When the dip coating method is selected, said method may involve partial or complete dipping of the mold into a reservoir containing the liquid polymeric mixture followed by curing the liquid polymeric mixture. The dipping and curing steps may be repeated to obtain the polymeric substrate having the plurality of imprints on the inner surface with different thickness.

In some embodiments, the mold of cylindrical shape (rod with negative structures) is dipped vertically into a reservoir that contains the liquid polydimethylsiloxane (PDMS). The cylindrical mold may then be removed from the reservoir and allow excess liquid polymeric to drain away leaving a layer of liquid PDMS of the surface of the mold followed by curing the liquid PDMS thermally or under UV exposure. The dipping and curing steps above may be repeated to achieve the required wall thickness of the tubing.

Based on the above, the present disclosure also provides a method of forming the plurality of imprints on the inner surface of the polymeric substrate comprising the steps of:

a) contacting the liquid polymeric mixture as defined above with the mold having the imprint forming surface thereon, wherein the contacting step is undertaken via a dip-coating method;

b) curing the liquid polymeric mixture of step a) to form said polymeric substrate having said plurality imprints on its inner surface, when cured; optionally repeating steps a) and b); and

c) removing said mold from said polymeric substrate.

For the method where the contacting step is undertaken via dip-coating process, the inner surface of the polymeric substrate may be the one in direct contact with the outer surface of the mold (such as the one represented as (109) in FIG. 1A, (125) in FIG. 1B or (135) in FIG. 1C). In the case where said polymeric substrate is in the form of tubing(s), its inner surface may be defined as a lumen. Exemplary embodiment of such inner surface of the polymeric substrate is depicted as (237) in FIG. 2B. The outer surface of the polymeric substrate, on the other hand, is the surface opposing the inner surface and is indicated as (239) in FIG. 2B. Since the outer surface of the mold is an imprint forming surface, the plurality of imprints formed on the inner surface of the polymeric substrate may be considered as the negative impression of the imprint of the outer surface of the mold.

In the above curing process, a curing agent may be added to facilitate the hardening or toughening process. The curing agent plays an important role in the curing kinetics, gel time, degree of curing, viscosity, curing cycle as well as the final properties of the cured polymer or polymeric mixture. The curing agents may include active hydrogen-containing compounds and their derivatives, anionic and cationic initiators and reactive cross-linkers.

When one or more curing agent is added, the curing agent may be mixed with the liquid polymeric mixture as defined above following a ratio of about 1:5 to about 1:50 of the curing agent:liquid polymeric mixture. The ratio may be about 1:10, about 1:20, about 1:25, about 1:30 or about 1:40.

The plurality of imprints aforementioned may be in the form of micro- or nano-structures or topographical features, which may be replicated on the inner luminal surface of tubings. Thus, the plurality of imprints above may be in the form of one-dimensional, two-dimensional or three-dimensional structure(s). Such structures may be continuous or discrete.

It is to be understood that the topographical features may be arranged in ordered arrays, non-ordered meta-surfaces or random.

The plurality of imprints on the inner surface of the polymeric substrate as defined above may have a lateral dimension in the range of about 20 nm to about 500 μm, about 20 nm to about 100 nm, about 20 nm to about 60 nm, about 60 nm to about 100 nm, about 100 nm to about 1 μm, about 100 nm to about 500 nm, about 500 nm to about 1 μm, about 1 μm to about 500 μm, about 1 μm to about 250 μm, about 250 μm to about 500 μm. More preferably, the lateral dimension above is in the range of about 20 nm to about 40 nm such as about 21 nm, about 22 nm, about 23 nm, about 24 nm, about 25 nm, about 26 nm, about 27 nm, about 28 nm, about 29 nm, about 30 nm, about 31 nm, about 32 nm, about 33 nm, about 34 nm, about 35 nm, about 36 nm, about 37 nm, about 38 nm, about 39 nm or about 40 nm.

The plurality of imprints on the inner surface of the polymeric substrate as defined herein may have a vertical dimension in the range of about 1 nm to about 500 μm, about 1 nm to about 100 nm, about 1 nm to about 50 nm, about 50 nm to about 100 nm, about 100 nm to about 1 μm, about 100 nm to about 500 nm, about 500 nm to about 1 μm, about 1 μm to about 500 μm, about 1 μm to about 250 μm, about 250 μm to about 500 μm. More preferably, the vertical dimension above is in the range of about 1 nm to about 5 nm such as about 1 nm, about 2 nm, about 3 nm, about 4 nm or about 5 nm.

The method disclosed in the present invention therefore provides micro- or nano-structures or the plurality of imprints that may impart various functionalities to the tubing such as an anti-bacterial, superhydrophobic surface to reduce frictional drag, turbulence promoting structures to enhance mixing in the tube or anisotropic wetting structures that can promote flow.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1 shows a number of alternate methods for fabricating micro- or nano-topographies around the external surface of inner cylindrical molds; FIG. 1A is nanoimprint method with the use of a polymeric film (105) imprinted on an inner surface (103), FIG. 1B is micro-machining method and FIG. 1C is self-assembly method using the solution with micro- or nano-particles (133).

FIG. 2 shows a schematic diagram of fabrication processes for tubings; FIG. 2A is a casting or cast molding method and FIG. 2B is a dip-coating method.

FIG. 3 shows a photograph of the assembly of the acetone flow/circulation system to dissolve inner cylindrical mold (305) made of PMMA.

FIG. 4 shows a photograph of silicone tubings with micro-structures formed on the inner luminal surface. Selective surface patterning (403) or whole surface area (401) patterning can be achieved.

FIG. 5 shows a schematic diagram demonstrating the fabrication of inner cylindrical mold using specific material which melts (503) and solidifies (505) to form the mold (507).

FIG. 6 shows a schematic diagram demonstrating the solvent-less removal of inner mold (605) whereby the inner mold is heated to a certain temperature (601).

FIG. 7 demonstrates a number of alternate methods for fabricating micro- or nano-topographies around the external surface of inner cylindrical molds; FIG. 7A is nanoimprint method with the use of a polymeric film (705) imprinted on an inner surface (703), FIG. 7B is micro-machining method, FIG. 7C is self-assembly method using the solution with micro- or nano-particles (733) and FIG. 7D is the recasting of inner cylindrical mold (751) method.

FIG. 8 shows a schematic diagram demonstrating the demolding of inner elastic hollow mold (805) by vacuum.

FIG. 9 shows a number of diagrams demonstrating the possible cross-sections of gratings or lines; FIG. 9A shows the square waveform (901), FIG. 9B shows the V-grooves (903), FIG. 9C shows the U-grooves (905) and FIG. 9D shows the orientation of the tubing longitudinal axis (909) and the circumferential direction (907).

FIG. 10 shows a number of scanning electron microscope (SEM) images of 500 nm diameter pillar (protrusions-1001) arrays on the inner luminal surface of silicone tubings (FIG. 10A, scale bar of 1 μm; and FIG. 10B, scale bar of 1 μm).

FIG. 11 shows a number of scanning electron microscope (SEM) images where FIG. 11A shows the cross-sectional view of inner luminal surface (1101) of silicone tubings (1103) lined with arrays of 2 μm (microns) square microwells, scale bar of 100 nm. FIG. 11B shows the plan view of 2 μm (microns) square microwells (1105) fabricated on inner luminal surface of silicone tubings, scale bar of 1 μm.

FIG. 12 shows the silicone tubing fabricated by dip-coating method to allow thin-walled tubing fabrication (left image), while the image on the right is an expanded view of the selected section of the image on the left showing patterns of 10 μm (microns) microwells of circular shape (1203) in a hexagonal array (1201).

FIG. 13 shows a number of scanning electron microscope (SEM) images indicating examples of hierarchical structures or multilevel three-dimensional (3D) structures which can be fabricated on flat films by nanoimprint lithography; FIG. 13A shows gratings (1301) that are aligned perpendicular to the larger trough-like (1303) structures, scale bar of 1 μm and FIG. 13B shows microwells in circular shapes (1305) and trough-like (1307) structures, scale bar of 1 μm.

FIG. 14 shows a photograph of an acetone bath (1401) containing the tubing with dissolvable inner mold (1403).

### DETAILED DESCRIPTION OF DRAWINGS

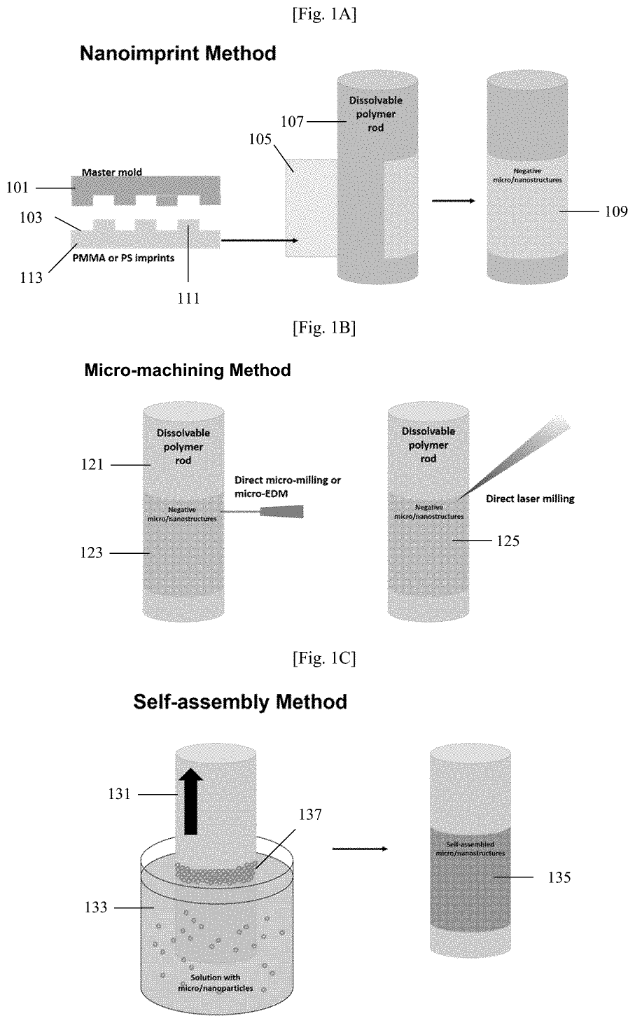

Referring to FIG. 1, FIG. 1A shows a schematic diagram of the nanoimprint method with the use of a two-dimensional (2D) flat master mold (101) to create micro- or nano-topographies (111) on the inner luminal surfaces of a polymeric film (103). The desired topographies were imprinted onto a thin freestanding polymer film (113). The imprinting temperature is above the glass transition temperature of the polymer film. The imprinted sheet (105) was adhered around a cylinder or polymer rod (107) by tape adhesive to form the polymer rod with the negative micro- or nano-structures on the outer surface (109). In this case, the cylindrical mold and adhesive must be dissolvable by the solvent in which the tubing is chemically resistant to. FIG. 1B shows a schematic diagram of the micro-machining method where the polymer cylinders (121) are directly machined by techniques such as but not limited to laser milling, micro-EDM or micro-milling to create micro- or nano-patterns (123 or 125) on the polymer rod (outer or external) surface. The techniques selectively remove material from defined positions on the cylinder external surface to create the desired micro- or nano-patterns (123 or 125). Such techniques enable the fabrication of seam-less patterning around the circumference of the rod. FIG. 1C shows a schematic diagram of the self-assembly method where the micro- or nano-topographies (135) can be achieved via the deposition of micro- or nano-particles (137) from a solution of micro- or nano-particles (133) onto the rod or cylindrical mold (131) by drawing a meniscus of micro- or nano-particle suspension along the length of the rod.

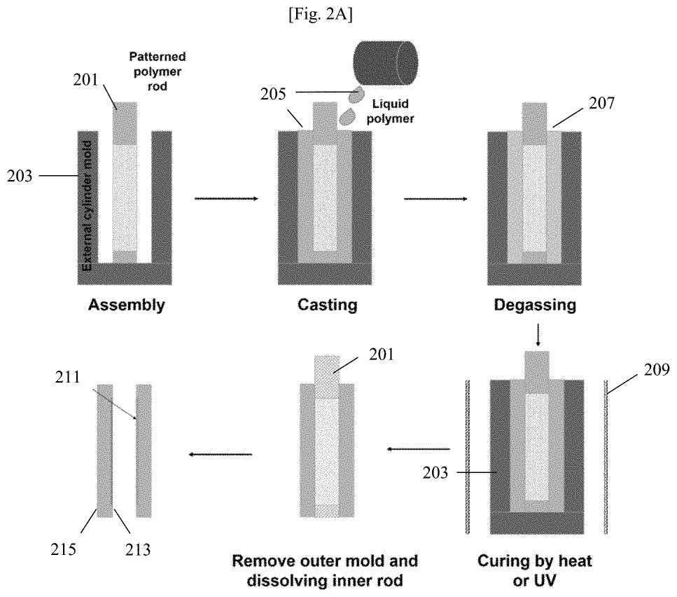

Referring to FIG. 2, FIG. 2A shows a schematic diagram of the casting or cast molding method where the liquid polymer (205) is cast to form the tubing into a mold, which comprises of two concentric layers whereby the inner layer is the patterned inner cylindrical mold (201), and the outer layer (203) is a tube that can be easily removed after the liquid polymer has cured. This outer layer can be peeled away or be dissolved by a solvent which the tubing is chemically resistant to. The liquid polymer is degassed (207) to remove bubbles and is cured either by heat or UV (209). The outer layer (203) is removed from the mold by dissolving it or peeling it away. The patterned inner cylindrical mold (201) is also removed by dissolving it, to form the micro- or nano-patterning (211) on the inner surfaces (213) of the tubes, whereas the outer surface (215) of the tubes does not have the micro- or nano-patterning. FIG. 2B shows a schematic diagram of the dip-coating method where the cylindrical mold or rod with the negative structures (221) is vertically dipped into the liquid pre-polymer mix (223). The cylindrical mold is then removed from the liquid polymer where the excess liquid polymer is allowed to drain away, leaving a thin layer of liquid polymer (227) on the mold surface. The liquid polymer is cured either thermally or under UV exposure (225). The dipping (229) and curing (231) steps are repeated to achieve the required wall thickness (233) of the tubing. The patterned inner cylindrical mold (221) is also removed by dissolving it to form the micro- or nano-patterning (235) on the inner surfaces (237) of the tubes, whereas the outer surface (239) of the tubes does not have the micro- or nano-patterning.

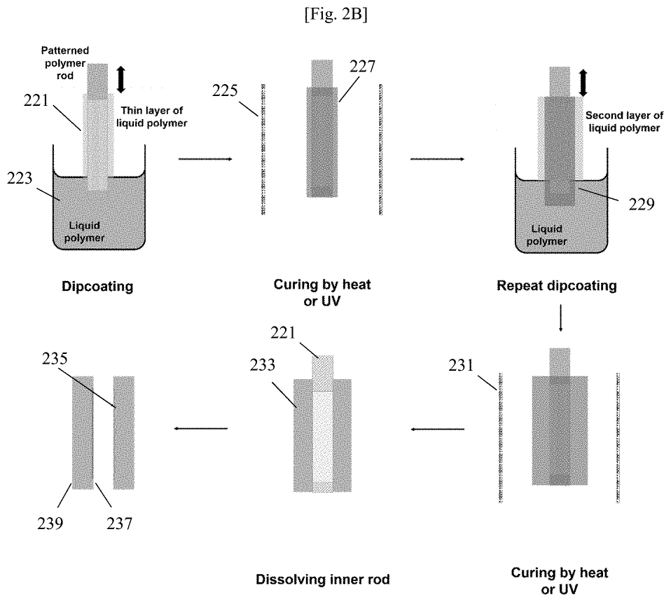

Referring to FIG. 3, FIG. 3 shows a photograph of the system that is connected to a peristatic pump (301) and an acetone reservoir (303) via silicone tubings to dissolve the inner cylindrical mold (305), where the solvent was pumped through the mold assembly and circulated continuously till the inner mold was dissolved. The used solvents in the reservoir can be further exchanged with fresh solvents to maintain the effective rate of dissolution. This method will allow faster dissolution of the inner mold and allow for fabrication of longer tubes.

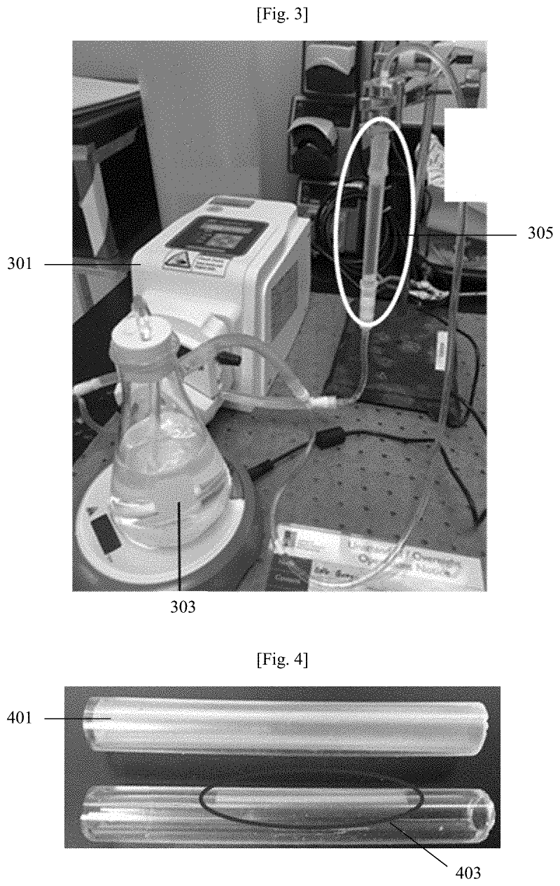

Referring to FIG. 4, FIG. 4 shows a photograph of silicone tubings with micro-structures formed on the inner luminal surface where the selective surface patterning (403) or whole surface area (401) patterning can be achieved.

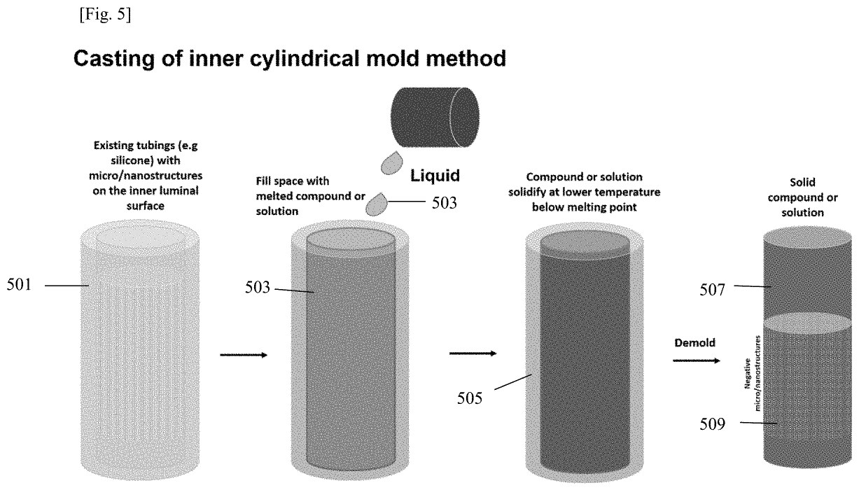

Referring to FIG. 5, FIG. 5 shows a schematic diagram of casting the inner cylindrical mold (507) using specific material which melts (503) and solidifies (505) to form the mold (507). By using existing tubings (e.g. silicone) (501) with micro- or nano-topographies on the inner luminal surface, the inner cylindrical mold (507) can be casted with a compound or solution (503). This compound or solution can be heated to melt into a liquid state (503) and solidify back (505) when the temperature is reduced. An example is paraffin wax. It is a solid at room temperature and has melting points ranging from about 48° C. to 70° C. depending on the grade of chain length of the hydrocarbon. When heated, the wax melts into a liquid and can be casted into the existing tubings (501) to form the inner cylindrical mold (507). Upon reduction in the temperature, the wax solidifies back and conforms to the shape of the tubing including the micro- or nano-topographies (509). After demolding, the wax inner cylindrical mold can be further used for casting new tubings.

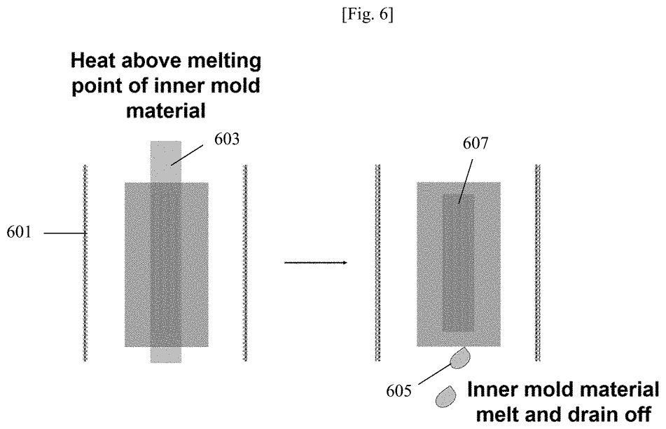

Referring to FIG. 6, FIG. 6 shows a schematic diagram of the solvent-less removal of inner mold (603) whereby the whole assembly will be heated to a certain temperature (601), typically is the temperature above the melting point or the vaporizing temperature of the inner mold material to melts or vaporizes away the inner mold (605). In the case of wax, the assembly can be heated above 50° C. to melt away the wax. The remaining tubings would have the micro- or nano-patterns (607) imprinted on.

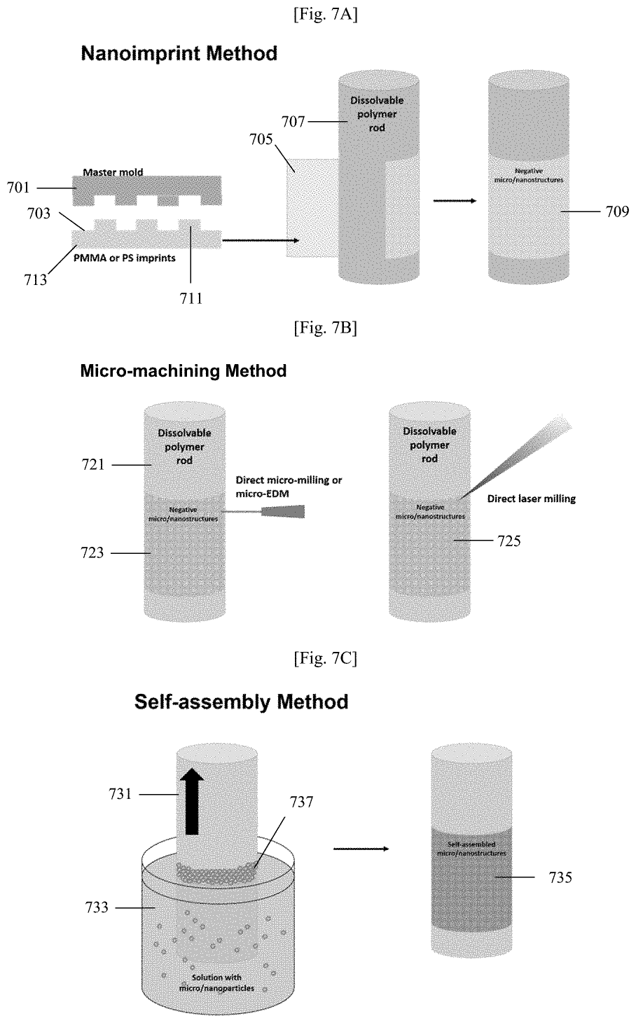

Referring to FIG. 7, FIG. 7A shows a schematic diagram of the nanoimprint method with the use of a two-dimensional (2D) flat master mold (701) to create micro- or nano-topographies (711) on the inner luminal surfaces of a polymeric film (703). The desired topographies were imprinted onto a thin freestanding polymer film (713). The imprinting temperature is above the glass transition temperature of the polymer film. The imprinted sheet (705) was adhered around a cylinder or polymer rod (707) by tape adhesive to form the polymer rod with the negative micro- or nano-structures on the outer surface (709). In this case, the cylindrical mold and adhesive must be dissolvable by the solvent in which the tubing is chemically resistant to. FIG. 7B shows a schematic diagram of the micro-machining method where the polymer cylinders (721) are directly machined by techniques such as but not limited to laser milling, micro-EDM or micro-milling to create micro- or nano-patterns (723 or 725) on the polymer rod surface. The techniques selectively remove material from defined positions on the cylinder external surface to create the desired micro- or nano-patterns (723 or 725). Such techniques enable the fabrication of seam-less patterning around the circumference of the rod. FIG. 7C shows a schematic diagram of the self-assembly method where the micro- or nano-topographies (735) can be achieved via the deposition of micro- or nano-particles (137) from a solution of micro- or nano-particles (733) onto the rod or cylindrical mold (731) by drawing a meniscus of micro- or nano-particle suspension along the length of the rod. FIG. 7D shows a schematic diagram of the recasting of inner cylindrical mold (751) method, where the negative relief structures of the desired micro- or nano-topographies (753) can be fabricated onto an elastic and hollow cylindrical mold (e.g. silicone) (751). The existing silicone tubings with the desired micro- or nano-topographies (753) on the inner luminal surface can also serve as a mold in fabricating a “daughter” hollow inner cylindrical mold (751). In the case, the mold (which is the existing silicone tubing) must be larger in diameter than the “daughter” mold. The space is then filled with the liquid polymer (755) and upon the curing and demolding steps; the “daughter” mold would contain the desired micro- or nano-topographies (753) from the existing silicone tubings.

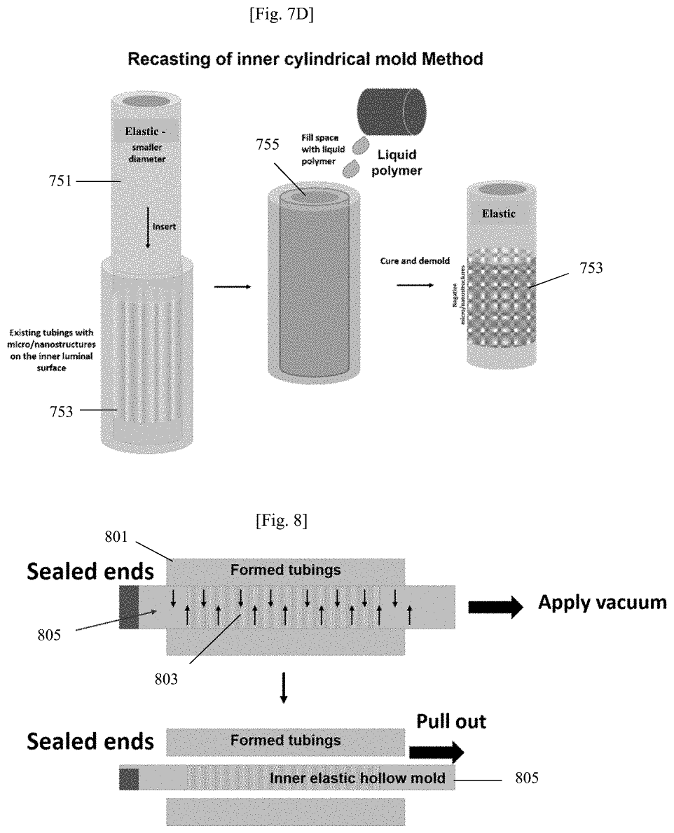

Referring to FIG. 8, FIG. 8 shows a schematic diagram demonstrating the demolding of inner elastic hollow mold (805) by vacuum, where the key process is the use of vacuum and the elasticity of the inner cylindrical mold to demold from the formed tubings (801). To remove the inner elastic mold (805), one end of the inner hollow mold is sealed and the other end of the inner hollow cylindrical mold is connected to a vacuum source. The pressure of the air (803) inside the elastic hollow cylindrical mold is reduced relative to the atmospheric pressure. This causes the hollow mold (805) to collapse within the tubings. The collapse of the inner mold (805) will effectively demold the hollow inner mold from the inner tubings walls and allow the inner mold to be removed from the inner space of the tubings. Due to the elastic nature of the hollow inner mold, the mold can be reused to cast for another piece of tubings after the vacuum is released.

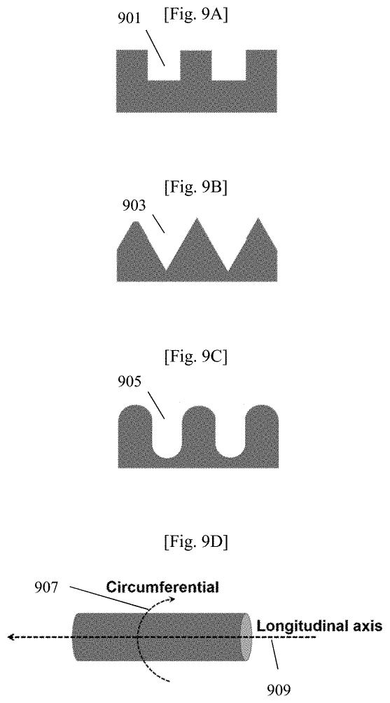

Referring to FIG. 9, FIG. 9A shows the cross-section view of the square waveform (901) which is one of the line grating features. FIG. 9B shows the cross-section view of the V-grooves (903) and FIG. 9C shows the cross-section view of the U-grooves (905) which are part of the line grating features. FIG. 9D shows that the lines grating can orientate parallel to the tubing longitudinal axis (909), perpendicular (circumferential direction-907), or diagonally.

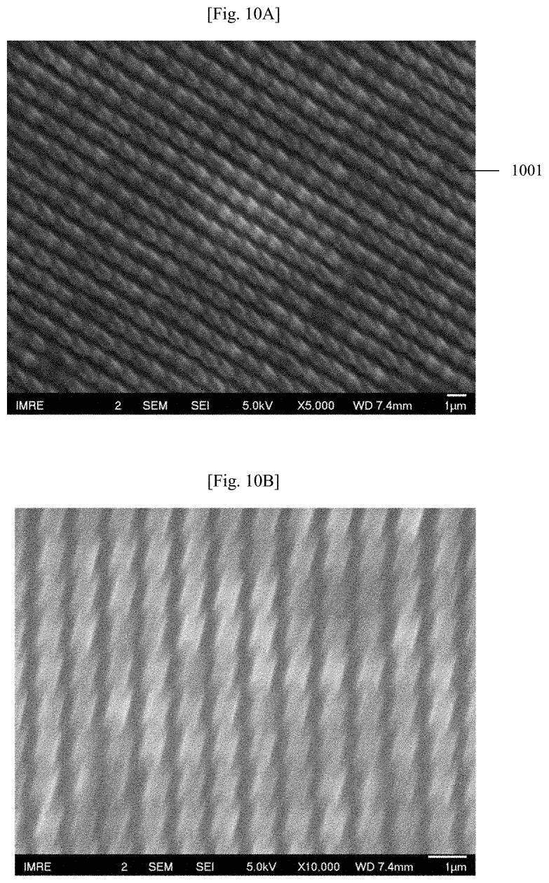

Referring to FIG. 10, FIG. 10A and FIG. 10B show a number of scanning electron microscope (SEM) images of the two-dimensional (2D) micro- or nano-structures that include regular arrays of protrusions (posts/pillars) and this is demonstrated by the 500 nm diameter pillar (protrusions-1001) arrays on the inner luminal surface of silicone tubings.

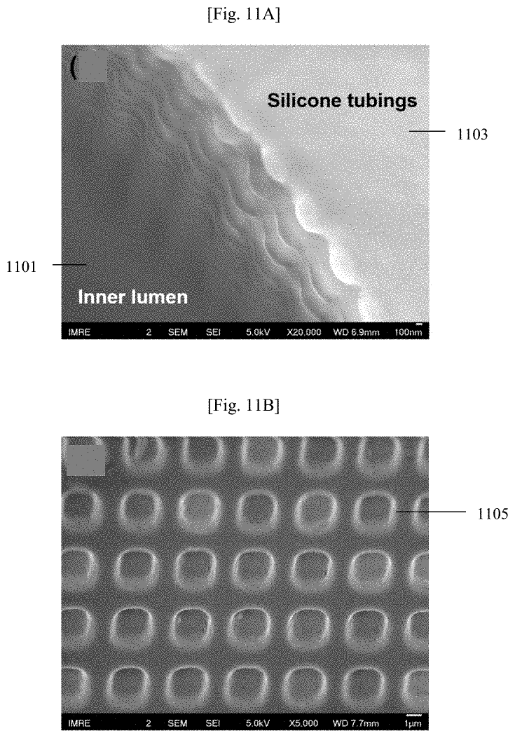

Referring to FIG. 11, FIG. 11 shows a number of scanning electron microscope (SEM) images of the two-dimensional (2D) micro- or nano-structures that include wells (pits), where FIG. 11A shows the cross-sectional view of inner luminal surface (1101) of silicone tubings (1103) lined with arrays of 2 μm (microns) square microwells. FIG. 11B shows the plan view of 2 μm (microns) square microwells (1105) fabricated on inner luminal surface of silicone tubings.

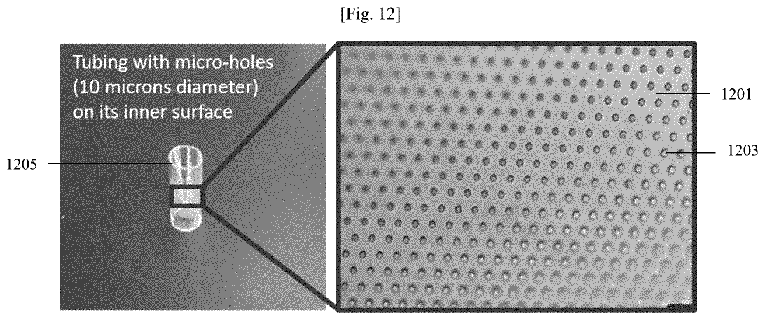

Referring to FIG. 12, FIG. 12 shows a number of images of the two-dimensional (2D) micro- or nano-structures that include micro-wells structures in the shape of circles, where the image on the left shows the silicone tubing (1205) fabricated by dip-coating method to allow thin-walled tubing fabrication, and the image on the right is the expanded view of the selection section from the image on the left, showing patterns that consist of 10 μm (microns) microwells of circular shape (1203) in a hexagonal array (1201).

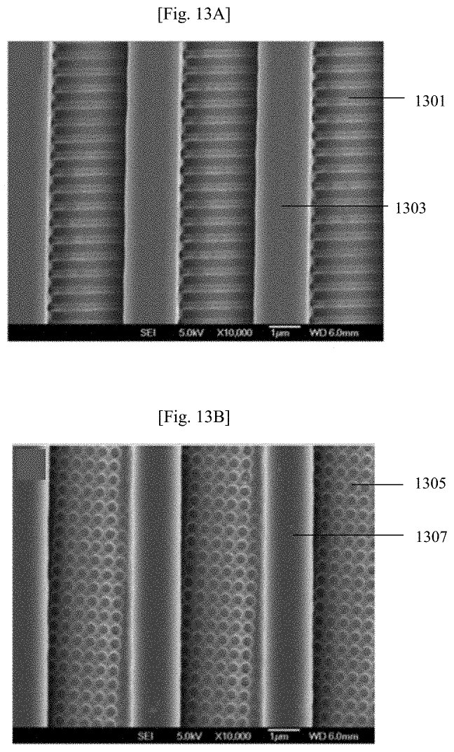

Referring to FIG. 13, FIG. 13 shows a number of scanning electron microscope (SEM) images of hierarchical or multi-level three-dimensional (3D) structures, which can be fabricated on flat films by nanoimprint lithography, where FIG. 13A shows gratings (1301) that are aligned perpendicular to the larger trough-like (1303) structures and FIG. 13B shows microwells in circular shapes (1305) and trough-like (1307) structures.

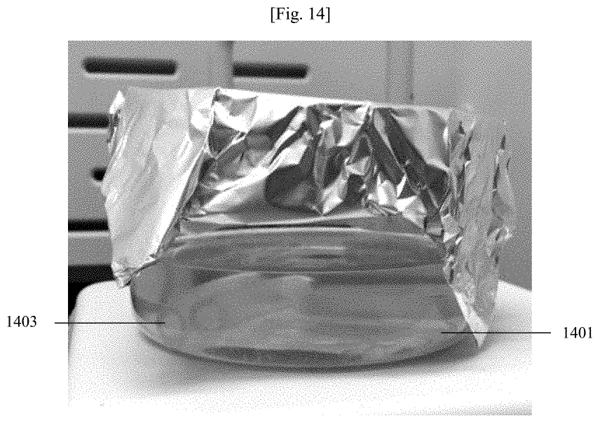

Referring to FIG. 14, FIG. 14 shows a photograph of an assembly being immersed in a container of solvent which is capable of dissolving the inner cylindrical mold completely, where the container of solvent is an acetone bath (1401) containing the tubing with dissolvable inner mold (1403).

### EXAMPLES

Non-limiting examples of the invention will be further described in greater detail by reference to specific Examples, which should not be construed as in any way limiting the scope of the invention.

### List of Abbreviations Used

H: hour(s)

m.p.: melting point

min: minute(s)

FDTS: perfluorodecyltrichlorosilane

PDMS: polydimethylsiloxane

PMMA: polymethylmethacrylate

PTFE: polytetrafluoroethylene (Teflon)

PS: polystyrene

Rt: room temperature

UV: ultraviolet irradiation

### Materials and Methods

Poly(dimethylsiloxane) or PDMS (under trademark Sylgard® 184) was provided by the Dow Chemical Company (Midland, Mich., United States). Acetone and chloroform were purchased from Merck (Kenilworth, N.J., United States of America) and used without further purification, unless specified otherwise. Polymethylmethacrylate (PMMA) free-standing films were obtained from Goodfellow Cambridge Ltd. (United Kingdom). Perfluorodecyltrichlorosilane (FDTS) was purchased from Gelest Inc. (Morrisville, Pa., United States of America). Other reagents or materials and/or solvent(s) than the above were purchased from Sigma-Aldrich Corp. (St. Louis, Mo., United States of America) and were used as received where otherwise noted in the experimental text below.

### Example 1—‘Solvent Dissolution of Dissolvable Mold’ Method

The method of imparting micro- or nano-topographies on the curved, inner surface of the tubing involves creating a negative of the desired topographies on the outer surface of a dissolvable cylinder or polymer rod which can be dissolved by a solvent in which the tubing is chemically resistant to. The tubing can be formed by cast molding or dip-coating, with the patterned cylinder serving as a template for the inner surface of the tubing. Discrete topographies in addition to continuous topographies (e.g. lines), can be created using this method.

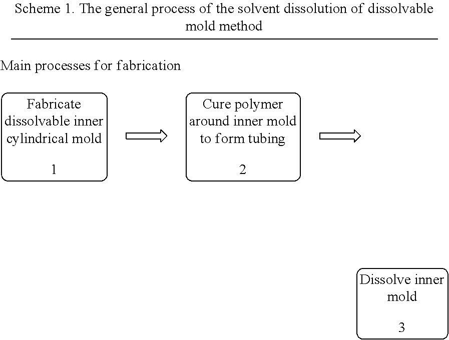

The following describes the sequential process that must be followed for the creation of the tubing:

1. Method to Create a Negative Relief of the Desired Topographies onto a Cylindrical Mold

This step enables the fabrication of the negative micro- or nano-features onto the cylindrical inner mold. The cylindrical inner mold can be a rod or a hollow tube. The hollow tube version allows solvents to be pumped and circulated through the inner mold and enhanced dissolution rate of the mold. The entire dissolvable inner mold embodiment must be dissolvable in the solvent. The cylindrical mold can be fabricated by nano-imprint, micro-machining or self-assembly methods as indicated in FIGS. 1A-1C.

### A) Nanoimprinting Method

The imprinting method allows two-dimensional (2D) flat master molds (101) to be used to create micro- or nano-topographies (111) on curved inner luminal surfaces (103). The desired topographies were first imprinted onto a thin freestanding polymer film (113) that can be dissolved by a solvent in which the tubing material is chemically resistant to. Imprinting temperature is above the glass transition temperature of the polymer film (FIG. 1A).

### B) Micro-Machining Method

Polymer cylinders (121) are directly machined by techniques such as but not limited to laser, micro-EDM or micro-milling to create micro- or nano-patterns (123 or 125) on the polymer rod surface (FIG. 1B). The techniques selectively remove material from defined positions on the cylinder external surface to create the desired micro- or nano-patterns (123 or 125). Such techniques enable the fabrication of seam-less patterning around the circumference of the rod.

### C) Self-Assembly of Organic or Inorganic Micro- or Nano-Spheres

Micro- or nano-topographies (135) can also be achieved via the deposition of particles (e.g. PS, PMMA, silica-137) onto the tubes or rods by drawing a meniscus of particle suspension from the solution with micro- or nano-particles (133) along the length of the rod (131) (FIG. 1C). This can result in either closely packed or loosely packed particles depending on the type of solvents and surfactants used. After the tube is molded, the particles can be dissolved in the same solvent as the rod (e.g. PS/PMMA can dissolve in acetone), or in a different solvent (e.g. silica can dissolve in sodium hydroxide).

2. Methods of Fabricating Tubings with Patterned Inner Surface

The inner cylindrical mold serves as the template for the fabrication of tubings. The tubings can be fabricated via two processes: casting or dip-coating. The diameter of the inner cylindrical mold defines the inner diameter of the tubings. The tubings' wall thickness and external diameter can be controlled by the outer cylindrical mold (casting method—FIG. 2A) or by the number of dips (dip-coating method—FIG. 2B).

### A) Casting or Cast Molding Method

In the cast molding method, the external cylindrical mold (203) defines the external diameter of the tubing (FIG. 2A). The external cylindrical mold can be made of various polymers, which include but not limited to polyethylene, polystyrene, polycarbonate, polymethylmethacrylate, polypropylene, and polytetrafluoroethylene. The external cylindrical mold can also be made of metal or glass or ceramics. External cylindrical molds may be coated with a layer of anti-stiction coatings such as PTFE (Teflon) or perfluorodecyltrichlorosilane (FDTS) to reduce adhesion between the tubings and the external mold, and facilitate demolding. The material used in the external cylindrical mold must not deform at the temperature used for curing the polymer of the tubings. In the case of UV-curable tubing material, the external cylindrical mold can be UV-transparent.

### Sequential Process of the Casting or Cast Molding Method is as Follows:

I. Casting the liquid polymer (e.g. PDMS-205) forming the tubing into a mold which comprises of two concentric layers whereby the inner layer is the patterned inner cylindrical mold (201), and the outer layer (203) is a tube that can be easily removed after the liquid polymer has cured. This outer layer (203) can be peeled away or be dissolved by a solvent which the tubing is chemically resistant to. The inner layer of the mold determines the inner diameter and surface of the tubing while the outer layer defines the outer diameter and surface of the tubing.

II. Degassing the liquid polymer to remove bubbles (207).

III. Curing the liquid polymer either by heat or UV (209). Curing conditions vary according to the temperature used. However, the curing temperature of the tubing polymer should be less than the glass transition temperature of the inner and outer mold. If curing temperature is higher than the glass transition temperature of the inner mold, the micro- or nano-topographies may be deformed.

IV. Removing the outer layer (203) of the mold by dissolving it or peeling it away.

### B) Dip-Coating Method

I. Dipping the cylindrical mold (rod with the negative structures) (221) vertically into liquid pre-polymer mix (e.g. PDMS) (223) (FIG. 2B).

II. Removing the cylindrical mold from the liquid polymer and allow excess liquid polymer to drain away leaving a thin layer of liquid polymer (227) on the mold surface.

III. Curing the liquid polymer either thermally or under UV exposure (225).

IV. Repeating the dipping and curing steps (I)-(III) to achieve the required wall thickness (233) of the tubing.

### 3. Methods for Dissolving Inner Mold

We disclose two processes which can be used to dissolve the inner cylindrical mold using a solvent such as acetone after the curing of the tubing material. After the inner mold was dissolved, the tubings can be rinsed with ethanol and IPA to remove the solvent.

### A) Solvent Bath Method

The assembly was immersed in a container of solvent capable of dissolving the inner cylindrical mold completely. In the case of PMMA or PS material, acetone is used. The bath can be heated above room temperature and stirred constantly to accelerate dissolution of the inner mold (FIG. 14).

### B) Solvent Pump-Through/Circulation Method

In this method, a hollow cylindrical mold was used in the tubing fabrication to allow solvent flow-through. The assembly was connected to a peristatic pump (301) and solvent reservoir (303) via silicone tubings. Solvent was pumped through the mold assembly and circulated continuously till the inner mold (305) was dissolved (FIG. 3). The used solvents in the reservoir can be further exchanged with fresh solvents to maintain the effective rate of dissolution. This method will allow faster dissolution of the inner mold and allow for fabrication of longer tubes.

### Example 2—Silicone Tubings Fabrication by Casting Method

For the current prototype, a nickel mold was used to imprint on polymethylmethacrylate (PMMA) films with thickness of 0.05 mm via a batch imprinter system at elevated temperature and pressure. The conditions used for imprinting is: 120 to 150° C., 40 bars, and 300 to 600 seconds. These films can also be fabricated in a high-throughput manner via other imprinter systems such as roll-to-roll imprinter and roll-to-plate imprinter. The imprinted sheet/film was then adhered around a cylinder (e.g. PMMA or PS) by tape adhesive (e.g. acrylic tape). The adhesive can also be liquid adhesive or a solvent adhesive for acrylics such as chloroform. The cylindrical mold and adhesive must be dissolvable by the solvent in which the tubing is chemically resistant to.

As mentioned above, micro or nano-topographies were transferred from a nickel or silicon master mold onto freestanding thin PMMA films (0.05 mm thick) by nanoimprinting lithography or hot embossing process. The nanoimprinting process was performed at 150° C., 40 bars, 600 seconds. The films were demolded at 30° C. The imprinted PMMA films were wrapped around the circumference of the PMMA hollow cylinder (6 mm in diameter) to form the inner dissolvable mold. The PMMA film was adhered to the cylinder by acrylic-based double-sided tape. The assembly of the mold for casting the tubings is formed by using an outer cylindrical mold (polystyrene drinking straw; 10 mm in diameter) which defines the external diameter of the tubing and an inner dissolvable mold which defines the inner diameter. The inner dissolvable mold is secured in the center of the outer hollow mold by blue-tack. The blue-tack holds the inner mold along the center axis relative to the external mold. The mold assembly was left upright. Sylgard 184 was prepared in the ratio of 1:10 (curing agent:pre-polymer mix) by weight. Silicone pre-polymer mixtures were then poured into the spaces between the inner and outer mold. The mixtures were degassed in a vacuum desiccator to remove bubbles in the mix for 1 to 2 hours with the assembly standing upright. The assembly with the silicone mix was then cured thermally at 80° C. curing temperature over a period of 18 hours. After curing, the outer mold was peeled away.

Selective surface patterning (403) or whole surface area (401) patterning can be achieved using the method disclosed herein as indicated in FIG. 4.

### Example 3—‘Solvent-Less Removal of Inner Cylindrical Mold’ Method

The key feature of this method is the use of an inner mold material which melts or vaporizes after increasing the temperature to above the material's melting or sublimation temperature.

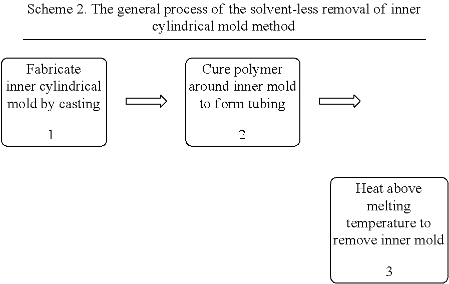

### 1. Fabrication of Inner Cylindrical Mold by Casting of a Material

Using existing tubings (e.g. silicone) with micro- or nano-topographies (501) on the inner luminal surface, the inner cylindrical mold can be casted with a compound or solution. This compound or solution can be heated to melt into a liquid state and solidify back when the temperature is reduced. An example is paraffin wax. It is a solid at room temperature and has melting points ranging from about 48° C. to 70° C. depending on the chain length of the hydrocarbon. When heated, the wax melts into a liquid (503) and can be casted into the existing tubings to form the inner cylindrical mold. Upon reduction in the temperature, the wax solidifies (505) back and conforms to the shape of the tubing including the micro- or nano-topographies (509). After demolding, the wax inner cylindrical mold (507) can be further used for casting new tubings (FIG. 5).

2. Methods of Fabricating Tubings with Patterned Inner Surface

With the inner cylindrical mold, tubings can be casted using similar methods described previously such as dip-coating and casting. UV-curable resins can be used in placed of thermally-cured resins in this case. An example is UV-curable polydimethylsiloxane (silicone-based) material.

### 3. Methods for Removing Inner Mold

The removal of the inner mold does not require any solvent. The whole assembly will be heated (6010) above the melting or vaporizing temperature of the inner mold material to melt or vaporize away the inner mold (605). In the case of paraffin wax, the assembly can be heated above 50° C. to melt away the wax. The temperature will not melt the silicone tubing material, which has a high degradation temperature (FIG. 6).

### Example 4—‘Tubing Fabrication and Vacuum-Assisted Demolding’ Method

This method is used to fabricate tubings with micro- or nano-topographies on the inner luminal surface. However, this method is independent from the other two methods described above. This method comprises of the following main processes:

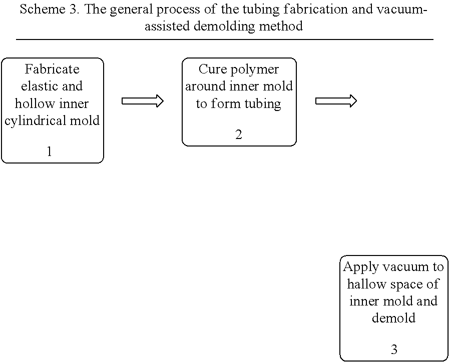

1. Method to Create a Negative Relief of the Desired Topographies onto an Elastic and Hollow Cylindrical Mold

Negative relief structures of the desired micro- or nano-topographies can be fabricated onto an elastic and hollow cylindrical mold (e.g. silicone) (751) by nanoimprint lithography method (FIG. 7A), micro-machining method (FIG. 7B) or self-assembly method (FIG. 7C) as previously described. The silicone tubings with the desired micro- or nano-topographies (753) on the inner luminal surface can also serve as a mold in fabricating “daughter” hollow inner cylindrical mold (FIG. 7D). In this case, the silicone tubings (acting as a mold) must be larger in diameter than the “daughter” mold.

2. Methods of Fabricating Tubings with Patterned Inner Surface

Processes for fabricating the tubings are similar to methods previously described which include casting and dip-coating methods.

### 3. Method to Demold by ‘Vacuum-Assisted’ Technique

The key process is the use of vacuum in conjunction with the elasticity of the inner cylindrical mold to demold from the formed tubings (801). After the tubings are cured around the inner and outer cylindrical molds, the outer mold can be peeled away physically. To remove the inner elastic mold, one end of the inner hollow mold is sealed and the other end of the inner hollow cylindrical mold is connected to a vacuum source (FIG. 8). The pressure of the air (803) inside the elastic hollow cylindrical mold is reduced relative to the atmospheric pressure. This causes the hollow mold (805) to collapse within the tubings. The collapse of the inner mold will effectively demold the hollow inner mold from the inner tubings walls and allow the inner mold to be removed from the inner space of the tubings. Due to the elastic nature of the hollow inner mold, the mold can be reused to cast for another piece of tubings after the vacuum is released.

### Example 5—Types of Micro- or Nano-Topographical Surfaces

The types of micro- or nano-topographical features which can be replicated on the inner luminal surface of tubings include continuous one-dimensional (1 D) patterns, discrete two-dimensional (2D) arrays, and three-dimensional (3D) hierarchical structures. Micro- or nano-topographical features which can be fabricated or replicated by nanoimprint lithography, micro-machining techniques or self-assembly can potentially be transferred to the inner luminal surface of the tubings via the method as defined above. The patterns can be ordered arrays, non-ordered meta-surfaces or random (e.g. random roughness). Lateral and vertical dimensions of the features can go down to 30 nm and 2 nm respectively depending on the formulation of the tubing polymer.

### Continuous Structures (One-Dimensional Structures)

Continuous or line grating features can include the cross-sections such as square waveform (901), V-grooves (903) and U-grooves (905) as shown in FIGS. 9A-9C. The lines grating can orientate parallel to the tubing longitudinal axis (909), perpendicular (circumferential direction) (907), or diagonally as shown in FIG. 9D.

### Discrete Protrusion or Well Structures (Two-Dimensional Structures)

Two-dimensional (2D) micro- or nano-structures can include regular arrays of protrusions (posts/pillars) (1001) (FIGS. 10A-10B) or wells (pits). The posts and wells structures can be in variety of shapes (include but not limited to circles (1203), squares (1105), triangles) as shown in FIGS. 11A-11B. The arrangement of wells or protrusions can include but not limited to hexagonal arrays (1201) (FIGS. 12A-12B) or square arrays.

### Hierarchical or Multilevel Structures (Three-Dimensional Structures)

Hierarchical or multilevel three-dimensional (3D) structures can be replicated on the inner luminal surface. A two-steps imprinting process can be performed on flat free-standing polymer films to achieve hierarchical micro- or nano-structures. Some examples of hierarchical or multilevel three-dimensional mold structures include the following as shown in FIGS. 13A-13B.

### High Aspect Ratio Features

Micro- or nano-protrusions or wells with high aspect ratio more than 1 can potentially be fabricated on the inner luminal surface. The method disclosed herein does not require physical demolding of the inner mold from the tubings. Therefore, this method is advantageous in minimizing physical damage and preserves the high aspect ratio structures.

### INDUSTRIAL APPLICABILITY

The imprinted polymeric substrate prepared by the method as defined above may be used generally in hydraulic applications. Hence, the polymeric substrate may be used as superhydrophobic tubings with reduced friction, tubings with enhanced passive mixing or tubings with anisotropic wetting structures that promote flow. The polymeric substrate prepared by the method as defined above may be used in medical applications. Hence, the polymeric substrate may be used as blood-handling tubings with reduced hemolysis, catheters with reduced biofouling or ultrasound-guided catheters with enhanced ultrasound visibility.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method of forming a plurality of imprints on an inner surface of a polymeric substrate comprising the steps of:
a) contacting a liquid polymeric mixture with a mold having an imprint forming surface thereon;
b) curing the liquid polymeric mixture of step a) to form said polymeric substrate having said plurality imprints on said inner surface, when cured; and
c) removing said mold from said polymeric substrate.

2. The method of claim 1, wherein said mold having said imprint forming surface thereon comprises a dissolvable material, temperature-dependent material or pressure-dependent material.

3. The method of claim 1, wherein the step of contacting said liquid polymeric mixture with said mold having said imprint forming surface thereon occurs in the presence or in the absence of an external mold.

4. The method of claim 2, wherein said dissolvable material is acrylic-based polymer, acrylate-based polymer, polystyrene or mixtures thereof.

5. The method of claim 2, wherein said temperature-dependent material is a mixture of two or more hydrocarbons having twenty to forty carbon atoms.

6. The method of claim 2, wherein said pressure-dependent material is an elastomer.

7. The method of claim 1, wherein the step of removing said mold from said polymeric substrate is undertaken in the presence of one or more solvents.

8. The method of claim 1, wherein the step of removing said mold from said polymeric substrate is undertaken in the absence of solvent.

9. The method of claim 1, the step of removing said mold from said polymeric substrate comprises the step of distorting the shape or size of said mold by subjecting said mold to a vacuum.

10. The method of claim 1, wherein said plurality of imprints on the inner surface of said polymeric substrate is a one-dimensional, two-dimensional or three-dimensional structure.

11. The method of claim 10, wherein said plurality of imprints on the inner surface of said polymeric substrate is continuous or discrete.

12. The method of claim 1, wherein said plurality of imprints on the inner surface of said polymeric substrate has a lateral dimension in the range of 20 nm to 40 nm.

13. The method of claim 1, wherein said plurality of imprints on the inner surface of said polymeric substrate has a vertical dimension in the range of 1 nm to 5 nm.

14. The method of claim 3, wherein said external mold comprises the same or different material as said mold.

15. The method of claim 1, wherein said liquid polymeric mixture comprises polymeric organosilicon compounds selected from the group consisting of polymethylhydrosiloxane (PMHS), polydimethylsiloxane (PDMS), polyethylmethylsiloxane (PEMS), polydiethylsiloxane (PDES) and blends thereof.

16. The method of claim 1, wherein the step of curing said liquid polymeric mixture is by heating or by UV irradiation.

17. A method of forming a mold having an imprint forming surface thereon, wherein said method is a nano-imprinting method, a micro-machining method or a self-assembly method.

18. The method of claim 17, wherein said nanoimprinting method comprises the steps of:
i) imprinting a surface of a polymeric film; and
ii) adhering the imprinted polymeric film onto an outer surface of a pre-mold,
wherein the non-imprinted surface of the polymeric film is in contact with the pre-mold to thereby form said mold having an imprint forming surface thereon.

19. A polymeric substrate prepared by the method of claim 1.

20. A mold prepared by the method of claim 17.
